(19) United States
(12) Patent Application Publication
(10) Pub. No.: US 2025/0201553 A1
(43) Pub. Date: Jun. 19, 2025

(54) METHODS FOR MAKING EUV PATTERNABLE HARD MASKS

(71) Applicant: Lam Research Corporation, Fremont, CA (US)

(72) Inventors: Chenghao Wu, San Jose, CA (US); Timothy William Weidman, Sunnyvale, CA (US); Katie Lynn Nardi, San Jose, CA (US)

(21) Appl. No.: 19/064,426

(22) Filed: Feb. 26, 2025

Related U.S. Application Data
(63) Continuation of application No. 15/733,598, filed on Sep. 10, 2020, now abandoned.
(60) Provisional application No. 62/782,578, filed on Dec. 20, 2018.
(60) Provisional application No. 62/670,644, filed on May 11, 2018.

(51) Int. Cl. H01L 21/02; G03F 7/004; G03F 7/16; G03F 7/26; H01L 21/033

(52) U.S. Cl. CPC H01L 21/02348; G03F 7/0042; G03F 7/167; G03F 7/26; H01L 21/0228; H01L 21/02304; H01L 21/0332; H01L 21/0337; H01L 21/02271

(57) ABSTRACT

Methods for making thin-films on semiconductor substrates, which may be patterned using EUV, include: mixing a vapor stream of an organometallic precursor with a vapor stream of a counter-reactant so as to form a polymerized organometallic material; and depositing the organometallic polymer-like material onto the surface of the semiconductor substrate. The mixing and depositing operations may be performed by chemical vapor deposition (CVD), atomic layer deposition (ALD), and ALD with a CVD component, such as a discontinuous, ALD-like process in which metal precursors and counter-reactants are separated in either time or space.

### CROSS-REFERENCE TO RELATED APPLICATIONS

An Application Data Sheet is filed concurrently with this specification as part of the present application. Each application that the present application claims benefit of or priority to as identified in the concurrently filed Application Data Sheet is incorporated by reference herein in their entireties and for all purposes.

### FIELD

The present technology relates to systems and methods for making lithographic masks for use in semiconductor fabrication. In particular, the present technology provides methods, devices and compositions for producing patternable hard masks on substrates used in the fabrication of semiconductor devices.

### BACKGROUND

The background description provided herein is for the purpose of generally presenting the context of the present technology. Work of the presently named inventors, to the extent it is described in this background section, as well as aspects of the description that may not otherwise qualify as prior art at the time of filing, are neither expressly nor impliedly admitted as prior art against the present technology.

The fabrication of semiconductor devices, such as integrated circuits, is a multi-step process involving photolithography. In general, the process includes the deposition of material on a wafer, and patterning the material through lithographic techniques to form structural features (e.g., contacts, vias, interconnects, transistors and circuitry) of the semiconductor device. The steps of a typical photolithography process known in the art include: preparing the substrate; applying a photoresist, such as by spin coating; exposing the photoresist to light in a desired pattern, causing the exposed areas of the photoresist to become more or less soluble in a developer solution; developing by applying a developer solution to remove either the exposed or the unexposed areas of the photoresist; and subsequent processing to create features on the areas of the substrate from which the photoresist has been removed, such as by etching or material deposition.

The evolution of semiconductor design has created the need, and has been driven by the ability, to create ever smaller features on semiconductor substrate materials. This progression of technology has been characterized in “Moore's Law” as a doubling of the density of transistors in dense integrated circuits every two years. Indeed, chip design and manufacturing has progressed such that modern microprocessors may contain billions of transistors and other circuit features on a single chip. Individual features on such chips may be on the order of 22 nanometers (nm) or smaller, in some cases less than 10 nm.

One challenge in manufacturing devices having such small features is the ability to reliably and reproducibly create photolithographic masks having sufficient resolution. Current photolithography processes typically use 193 nm ultraviolet (UV) light to expose a photoresist. The fact that the light has a wavelength significantly greater than the desired size of the features to be produced on the semiconductor substrate creates inherent issues. Achieving feature sizes smaller than the wavelength of the light requires use of complex resolution enhancement techniques, such as multipatterning. Thus, there is significant interest and research effort in developing photolithographic techniques using shorter wavelength light, such as extreme ultraviolet radiation (EUV), having a wavelength of from 10 nm to 15 nm, e.g., 13.5 nm.

EUV photolithographic processes can present challenges, however, including low power output and loss of light during patterning. Traditional organic chemically amplified resists (CAR) similar to those used in 193 nm UV lithography have potential drawbacks when used in EUV lithography, particularly as they have low absorption coefficients in EUV region and the diffusion of photo-activated chemical species can result in blur or line edge roughness. Furthermore, in order to provide the etch resistance required to pattern underlying device layers, small features patterned in conventional CAR materials can result in high aspect ratios at risk of pattern collapse. Accordingly, there remains a need for improved EUV photoresist materials, having such properties as decreased thickness, greater absorbance, and greater etch resistance.

### SUMMARY

The present technology provides methods for making thin-films on substrates, particularly semiconductor substrates, which may be patterned using EUV. Such methods include those where polymerized organometallic materials are produced in the vapor phase and deposited on a substrate. In particular, methods for making EUV-patternable thin films on a surface of a semiconductor substrate comprise: mixing a vapor stream of an organometallic precursor with a vapor stream of a counter-reactant so as to form a polymerized organometallic material; and depositing the organometallic polymer-like material onto the surface of the semiconductor substrate. In some embodiments, more than one organometallic precursor is included in the vapor stream. In some embodiments, more than one counter-reactant is included in the vapor stream. In some embodiments, the mixing and depositing operations are performed in a continuous chemical vapor deposition (CVD), an atomic layer deposition (ALD) process, or ALD with a CVD component, such as a discontinuous, ALD-like process in which metal precursors and counter-reactants are separated in either time or space. The present technology also provides methods for forming a pattern on a surface of a semiconductor material comprising exposing an area of an EUV-patternable thin film made according to the present technology using a patterned beam of EUV light, typically under relatively high vacuum, and then removing the wafer from vacuum and performing a post exposure bake in ambient air. The exposure results in one or more exposed regions, such that the film comprises one or more unexposed regions that have not been exposed to EUV light. Further processing of the coated substrate may exploit chemical and physical differences in the exposed and unexposed regions.

Further areas of applicability of the present technology will become apparent from the detailed description, the claims and the drawings. The detailed description and specific examples are intended for purposes of illustration only and are not intended to limit the scope of the technology.

### BRIEF DESCRIPTION OF THE DRAWINGS

The present technology will become more fully understood from the detailed description and the accompanying drawings, wherein:

FIG. 1 depicts an exemplary chemical reaction scheme of the present technology.

FIG. 2 is a flowchart depicting aspects of an exemplary process for deposition and processing of films of the present technology.

FIG. 3 depicts an exemplary process for making EUV defined patterns according to the present technology.

FIG. 4 depicts another exemplary process for generating patterns according to the present technology.

FIG. 5a, FIG. 5b, and FIG. 5c provide scanning electron microscope images of exemplary substrates made according to Example 1, having patterned features made using methods of the present technology.

FIG. 6a and FIG. 6b provide scanning electron microscope images of exemplary substrates made according to Example 2, having patterned features made using methods of the present technology.

FIG. 7a and FIG. 7b provide scanning electron microscope images of additional exemplary substrates made according to Example 2, having patterned features made using methods of the present technology.

FIG. 8 provides scanning electron microscope images of exemplary substrates with underlying features made according to Example 3, having patterned features made using methods of the present technology.

### DETAILED DESCRIPTION

The following description of technology is merely exemplary in nature of the subject matter, manufacture and use of one or more inventions, and is not intended to limit the scope, application, or uses of any specific invention claimed in this application or in such other applications as may be filed claiming priority to this application, or patents issuing therefrom. A non-limiting discussion of terms and phrases intended to aid understanding of the present technology is provided at the end of this Detailed Description.

As discussed above, the present technology provides methods for making polymerized thin-films on semiconductor substrates, which may be patterned using EUV. Such methods include those where polymerized organometallic materials are produced in a vapor and deposited on a substrate.

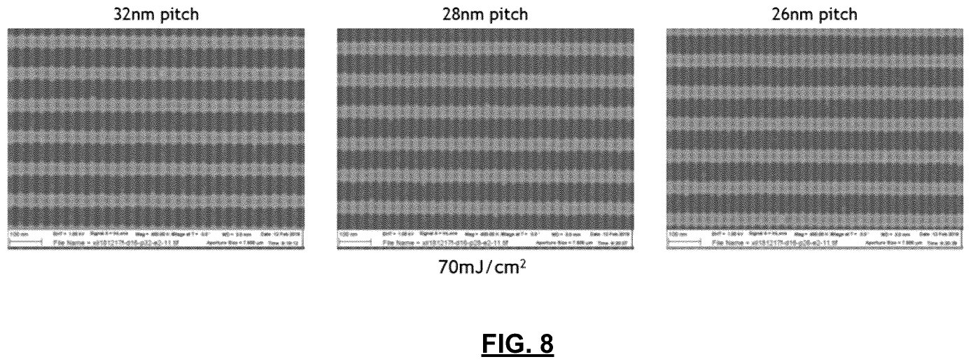

Substrates may include any material construct suitable for photolithographic processing, particularly for the production of integrated circuits and other semiconducting devices. In some embodiments, substrates are silicon wafers. Substrates may be silicon wafers upon which features have been created (“underlying features”), having an irregular surface topography. (As referred to herein, the “surface” is a surface onto which a film of the present technology is to be deposited or that is to be exposed to EUV during processing.) Such underlying features may include regions in which material has been removed (e.g., by etching) or regions in which materials have been added (e.g., by deposition) during processing prior to conducting a method of this technology. Such prior processing may include methods of this technology or other processing methods in an iterative process by which two or more layers of features are formed on the substrate. Without limiting the mechanism, function or utility of present technology, it is believed that, in some embodiments, methods of the present technology offer advantages relative to methods among those known in the art in which photolithographic films are deposited on the surface of substrates using spin casting methods. Such advantages may derive from the conformance of the films of the present technology to underlying features without “filling in” or otherwise planarizing such features, and the ability to deposit films on a wide variety of material surfaces. An exemplary surface having underlying features, upon which a film of the present technology has been deposited, is depicted in FIG. 8, which is further referenced in Example 3, below.

### Polymerized Thin Films

The present technology provides methods by which EUV-sensitive thin films are deposited on a substrate, such films being operable as resists for subsequent EUV lithography and processing. Such EUV-sensitive films comprise materials which, upon exposure to EUV, undergo changes, such as the loss of bulky pendant substituents bonded to metal atoms in low density M-OH rich materials, allowing their crosslinking to denser M-O-M bonded metal oxide materials. Through EUV patterning, areas of the film are created that have altered physical or chemical properties relative to unexposed areas. These properties may be exploited in subsequent processing, such as to dissolve either unexposed or exposed areas, or to selectively deposit materials on either the exposed or unexposed areas. In some embodiments, the unexposed film has a hydrophobic surface and the exposed film has a hydrophilic surface (it being recognized that the hydrophilic properties of exposed and unexposed areas are relative to one another) under the conditions at which such subsequent processing is performed. For example, the removal of material may be performed by leveraging differences in chemical composition, density and cross-linking of the film. Removal may be by wet processing or dry processing, as further described below.

The thin films are, in various embodiments, organometallic materials, comprising SnOₓ or other metal oxides moieties. The organometallic compounds may be made in a vapor phase reaction of an organometallic precursor with a counter reactant. In various embodiments, the organometallic compounds are formed through mixing specific combinations of organometallic precursors having bulky alkyl groups or fluoroalkyl with counter-reactants and polymerizing the mixture in the vapor phase to produce a low-density, EUV-sensitive material that deposit onto the substrate.

In various embodiments, organometallic precursors comprise at least one alkyl group on each metal atom that can survive the vapor-phase reaction, while other ligands or ions coordinated to the metal atom can be replaced by the counter-reactants. Organometallic precursors include those of the formula

$${M}_{a} {R}_{b} {L}_{c} \qquad ( Formula 1 )$$

wherein: M is a metal with a high EUV absorption cross-section; R is alkyl, such as CₙH₂ₙ₊₁, preferably wherein n>3; L is a ligand, ion or other moiety which is reactive with the counter reactant; a≥1; b≥1; and c≥1.

In various embodiments, M has an atomic absorption cross section equal to or greater than 1×10⁷ cm²/mol. M may be, for example, selected from the group consisting of tin, bismuth, antimony and combinations thereof. In some embodiments, M is tin. R may be fluorinated, e.g., having the formula CₙFₓH₍₂ₙ₊₁₎. In various embodiments, R has at least one beta-hydrogen or beta-fluorine. For example, R may be selected from the group consisting of i-propyl, n-propyl, t-butyl, i-butyl, n-butyl, sec-butyl, n-pentyl, i-pentyl, t-pentyl, sec-pentyl, and mixtures thereof. L may be any moiety readily displaced by a counter-reactant to generate an M-OH moiety, such as a moiety selected from the group consisting of amines (such as dialkylamino, monalkylamino), alkoxy, carboxylates, halogens, and mixtures thereof.

Organometallic precursors may be any of a wide variety of candidate metal-organic precursors. For example, where M is tin, such precursors include t-butyl tris(dimethylamino) tin, i-butyl tris(dimethylamino) tin, n-butyl tris(dimethylamino) tin, sec-butyl tris(dimethylamino) tin, i-propyl(tris)dimethylamino tin, n-propyl tris(diethylamino) tin, and analogous alkyl(tris) (t-butoxy) tin compounds such as t-butyl tris(t-butoxy) tin. In some embodiments, the organometallic precursors are partially fluorinated.

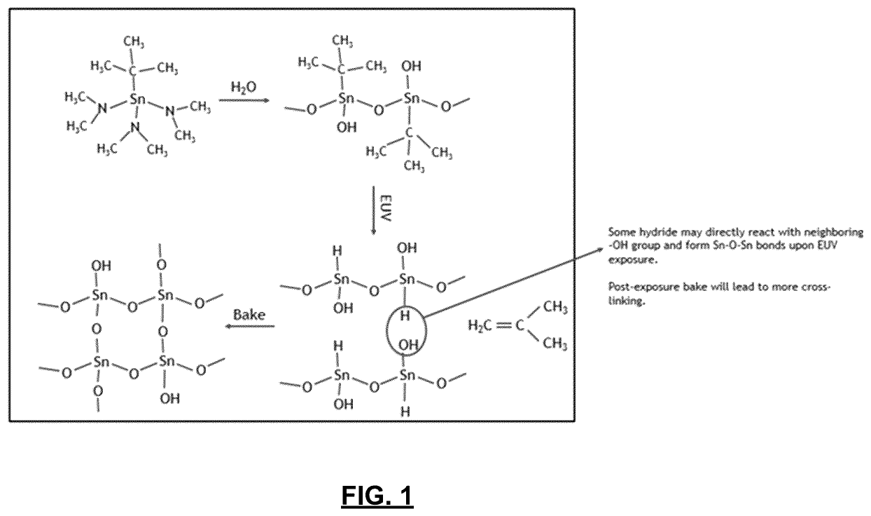

Counter-reactants preferably have the ability to replace the reactive moieties ligands or ions (e.g., L in Formula 1, above) so as to link at least two metal atoms via chemical bonding. Counter-reactants can include water, peroxides (e.g., hydrogen peroxide), di- or polyhydroxy alcohols, fluorinated di-or polyhydroxy alcohols, fluorinated glycols, and other sources of hydroxyl moieties. In various embodiments, a counter-reactant reacts with the organometallic precursor by forming oxygen bridges between neighboring metal atoms. Other potential counter-reactants include hydrogen sulfide and hydrogen disulfide, which can crosslink metal atoms via sulfur bridges. An exemplary process by which a polymerized organometallic material is formed is depicted in FIG. 1.

The thin films may include optional materials in addition to an organometallic precursor and counter-reactants to modify the chemical or physical properties of the film, such as to modify the sensitivity of the film to EUV or enhancing etch resistance. Such optional materials may be introduced, such as by doping during vapor phase formation prior to deposition on the substrate, after deposition of the film, or both. In some embodiments, a gentle remote H2 plasma may be introduced so as to replace some Sn-L bonds with Sn—H, which can increase reactivity of the resist under EUV.

### Film Deposition

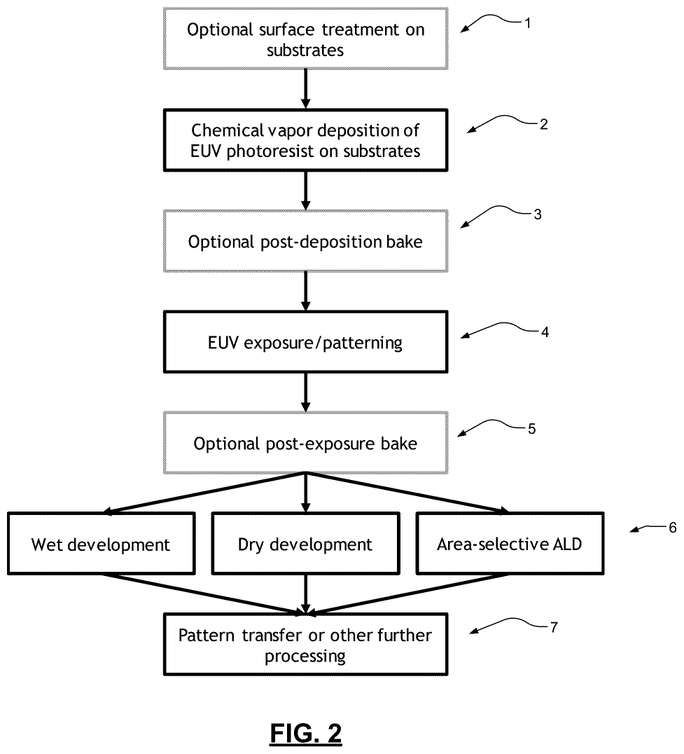

An exemplary process for deposition and processing of films of the present technology is depicted in FIG. 2. In some embodiments, methods comprise a pre-treatment 1 to improve the adhesion of the film to the substrate. The EUV film may then be deposited 2 on the substrate.

In various embodiments, the EUV-patternable films are made and deposited on the substrate using vapor deposition equipment and processes among those known in the art. In such processes, the polymerized organometallic material is formed in vapor phase or in situ on the surface of the substrate. Suitable processes include, for example, chemical vapor deposition (CVD), atomic layer deposition (ALD), and ALD with a CVD component, such as a discontinuous, ALD-like process in which metal precursors and counter-reactants are separated in either time or space.

In general, methods comprise mixing a vapor stream of an organometallic precursor with a vapor stream of a counter-reactant so as to form a polymerized organometallic material, and depositing the organometallic material onto the surface of the semiconductor substrate. As will be understood by one of ordinary skill in the art, the mixing and depositing aspects of the process may be concurrent, in a substantially continuous process.

In an exemplary continuous CVD process, two or more gas streams, in separate inlet paths, of organometallic precursor and source of counter-reactant are introduced to the deposition chamber of a CVD apparatus, where they mix and react in the gas phase, to form agglomerated polymeric materials (e.g., via metal-oxygen-metal bond formation). The streams may be introduced, for example, using separate injection inlets or a dual-plenum showerhead. The apparatus is configured so that the streams of organometallic precursor and counter-reactant are mixed in the chamber, allowing the organometallic precursor and counter-reactant to react to form a polymerized organometallic material. Without limiting the mechanism, function or utility of present technology, it is believed that the product from such vapor-phase reaction becomes heavier in molecular weight as metal atoms are crosslinked by counter-reactants, and is then condensed or otherwise deposited onto the substrate. In various embodiments, the steric hindrance of the bulky alkyl groups prevents the formation of densely packed network and produces porous, low density films.

The CVD process is generally conducted at reduced pressures, such as from 10 milliTorr to 10 Torr. In some embodiments, the process is conducted at from 0.5 to 2 Torr. The temperature of the substrate is preferably at or below the temperature of the reactant streams. For example, the substrate temperature may be from 0° C. to 250° C., or from ambient temperature (e.g., 23° C.) to 150° C. In various processes, deposition of the polymerized organometallic material on the substrate occurs at rates inversely proportional to surface temperature.

The thickness of the EUV-patternable film formed on the surface of the substrate may vary according to the surface characteristics, materials used, and processing conditions. In various embodiments, the film thickness may range from 0.5 nm to 100 nm, and is preferably of sufficient thickness to absorb most of the EUV light under the conditions of EUV patterning. For example, the overall absorption of the resist film may be 30% or less (e.g., 10% or less, or 5% or less) so that the resist material at the bottom of the resist film is sufficiently exposed. In some embodiments, the film thickness is from 10 to 20 nm. Without limiting the mechanism, function or utility of present technology, it is believed that, unlike wet, spin-coating processes of the art, the processes of the present technology have fewer restrictions on the surface adhesion properties of the substrate, and therefore can be applied to a wide variety of substrates. Moreover, as discussed above, the deposited films may closely conform to surface features, providing advantages in forming masks over substrates, such as substrates having underlying features, without “filling in” or otherwise planarizing such features.

### EUV Patterning

The present technology also provides methods wherein the deposited film is patterned by exposing a region of the film to EUV light. With further reference to FIG. 2, the patterning 4 may follow an optional post-deposition baking 3 of the film. In such patterning, the light is focused on one or more regions of the coated substrate. The exposure to EUV is typically performed such that the film comprises one or more regions that are not exposed to EUV light. The resulting film may comprise a plurality of exposed and unexposed regions, creating a pattern consistent with the creation of transistor or other features of a semiconductor device, formed by addition or removal of material from the substrate in subsequent processing of the film and substrate. EUV devices and imaging methods among useful herein include methods known in the art.

In particular, as discussed above, areas of the film are created through EUV patterning that have altered physical or chemical properties relative to unexposed areas. For example, in exposed areas, metal-carbon bond cleavage may occur via beta-hydride elimination, leaving behind reactive and accessible metal hydride functionality that can be converted to hydroxide and cross-linked metal oxide moieties via metal-oxygen bridges, which can be used to create chemical contrast either as a negative tone resist or as a template for hard mask. In general, a greater number of beta-H in the alkyl group results in a more sensitive film. Following exposure, the film may be baked, so as to cause additional cross-linking of the metal oxide film. This reaction chemistry is depicted in FIGS. 1, 3 and 4. The difference in properties between exposed and unexposed areas may be exploited in subsequent processing, such as to dissolve unexposed areas or to deposit materials on the exposed areas.

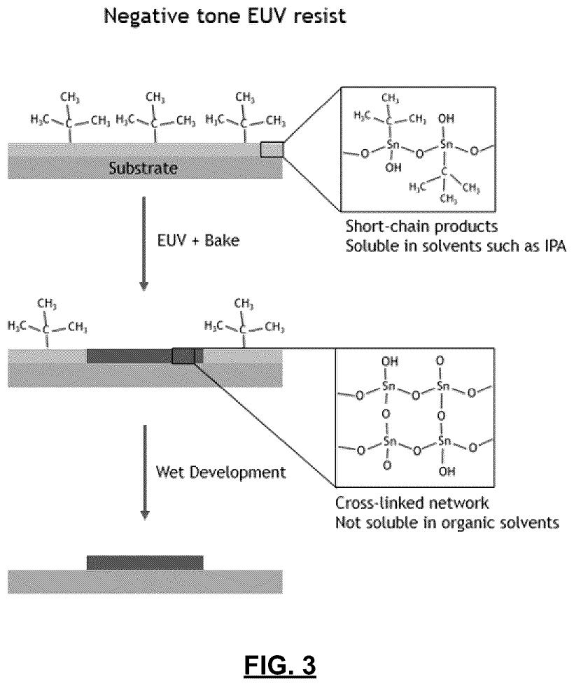

Such methods can be used for patterning in different ways. With further reference to FIG. 2, in some embodiments, post exposure baking 5 can facilitate the removal of alkyl group inside the film in a negative tone resist method. Such a negative tone resist method is depicted in FIG. 3. Without limiting the mechanism, function or utility of present technology, EUV exposure, for example, at doses of from 10 mJ/cm² to 100 mJ/cm², may alleviate steric hindrance and provide space for the low-density film to collapse. In addition, reactive metal-H bond generated in the beta-hydride elimination reactions can react with neighboring active groups such as hydroxyls in the film, leading to further cross-linking and densification, and creating chemical contrast between exposed and unexposed area.

This material contrast can then be used in subsequent processing, as shown in FIG. 2. Such processing 6 may include wet development, dry development or area-selective ALD. For example wet or dry development processes may remove the unexposed regions and leave the exposed regions.

In a wet development process, the chemical changes in the exposed areas result in the formation of more cross-linked materials with larger molecular weight and significant decrease in solubility in selective organic solvents. Non-cross-linked regions may be removed by use of suitable organic solvents, such as isopropyl alcohol, n-butyl acetate, or 2-heptanone. An unexpected benefit of the dry deposition of the films is that the films are completely soluble. Without limiting the mechanism, function or utility of present technology, this benefit may be related to the vapor-phase polymerization/condensation that occurs during deposition, possibly forming cyclic oligomers that are readily soluble in select solvents.

Selective dry etching may also be performed exploiting differences related to the composition, extent of cross-linking, and film density. In some embodiments of the present technology, a film of the present technology is vapor-deposited on a substrate. The film is then patterned directly by EUV exposure, and the pattern is developed using a dry method to form a metal oxide-containing mask. Methods and equipment among those useful in such processes are described in U.S. Patent Application 62/782,578, Volosskiy et al, filed Dec. 20, 2018 (incorporated by reference herein).

Such dry development processes can be done by using either a gentle plasma (high pressure, low power) or a thermal process while flowing a dry development chemistry such as BCl₃ (boron tricholoride) or other Lewis Acid. In some embodiments, BCl₃ is able to quickly remove the unexposed material, leaving behind a pattern of the exposed film that can be transferred into the underlying layers by plasma-based etch processes, for example conventional etch processes.

Plasma processes include transformer coupled plasma (TCP), inductively coupled plasma (ICP) or capacitively coupled plasma (CCP), employing equipment and techniques among those known in the art. For example, a process may be conducted at a pressure of >5 mT (e.g., >15 mT), at a power level of <1000 W (e.g., <500 W). Temperatures may be from 0 to 300° C. (e.g., 30 to 120° C.), at flow rate of 100 to 1000 standard cubic centimeters per minute (sccm), e.g., about 500 sccm, for from 1 to 3000 seconds (e.g., 10-600 seconds).

In thermal development processes, the substrate is exposed to dry development chemistry (e.g., a Lewis Acid) in a vacuum chamber (e.g., oven). Suitable chambers can include a vacuum line, a dry development chemistry gas (e.g., BCl₃) line, and heaters for temperature control. In some embodiments, the chamber interior can be coated with corrosion resistant films, such as organic polymers or inorganic coatings. One such coating is polytetrafluoroethene ((PTFE), e.g., Teflon 1M). Such materials can be used in thermal processes of this technology without risk of removal by plasma exposure.

In various embodiments, methods of the present technology combine all dry steps of film formation by vapor deposition, (EUV) lithographic photopatterning and dry development. In such processes, a substrate may directly go to a dry development/etch chamber following photopatterning in an EUV scanner. Such processes may avoid material and productivity costs associated with a wet development. Alternatively, a post exposure bake step during which the exposed regions undergo further crosslinking to form a denser SnO-like network may be conducted in the development chamber, or another chamber.

Without limiting the mechanism, function or utility of present technology, dry processes of the present technology may provide various benefits relative to wet development processes among those known in the art. For example, dry vapor deposition techniques described herein can be used to deposit thinner and more defect free films than can be applied using spin-coating techniques, and that the exact thickness of the deposited film can be modulated and controlled simply by increasing or decreasing the length of the deposition step or sequence. Accordingly, a dry process may provide more tunability and give further critical dimension (CD) control and scum removal. Dry development can improve performance (e.g., prevent line collapse due to surface tension in wet development) and enhance throughput (e.g., by avoiding wet development track). Other advantages may include eliminating the use of organic solvent developers, reduced sensitivity to adhesion issues, and a lack of solubility-based limitations.

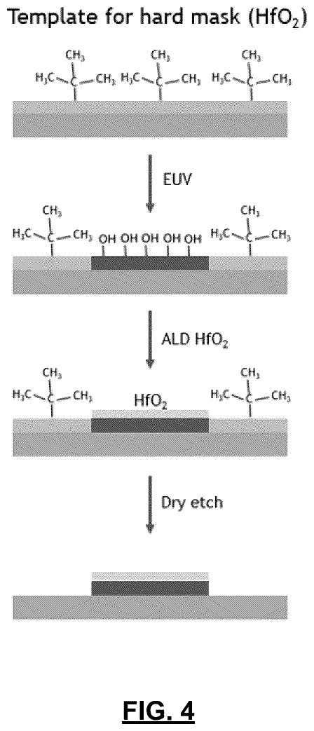

EUV-patterned thin films can also be used as a template for area selective deposition of a hard mask, as depicted in FIG. 4. In some embodiments, the removal of surface alkyl groups from the deposited organometallic polymer film can create patterns with regions of reactive surface moieties that can be used for bonding with a secondary material such as metal oxide precursors, applied to the surface of the substrate. Such patterns may comprise hydrophilic hydride or hydroxide exposed surfaces, and hydrophobic, bulky-alkyl-group-covered, unexposed regions. Such processes use relatively low doses of EUV light (e.g., from 1 mJ/cm² to 40 mJ/cm²). This can enable selective deposition of a secondary material by surface-driven processes such as atomic layer deposition (ALD) and electroless deposition (ELD).

For example, formation of the hard mask by ALD is a surface-driven process that requires nucleation sites such as hydroxyl groups where the precursor can adsorb. In the unexposed region, the surface is terminated with bulky alkyl groups which are both inert to ALD and act to sterically block hydroxyl groups. The exposed area, on the other hand, is covered with active hydride and/or hydroxyl functionality which can serve as nucleation sites for an ALD process. The difference in surface reactivity can be used to selectively deposit etch-resistant materials on exposed area, creating a hard mask for potential dry etch/dry development. For this application, only surface alkyl groups need to be removed under EUV exposure. The desired film thickness of the ALD may range from 0.5 nm-30 nm. The ALD precursor may also diffuse into the exposed resist and nucleate inside the exposed areas. The ALD may be either a metal or a metal oxide film and the ALD deposition temperature may range from 30° C.-500° C., e.g., 30° C.-210° C. The resist film thicknesses ranging from 0.5 nm-40 nm may be appropriate. In some embodiments, thicker films may provide some advantages because the resist film collapse may be used to prevent mushrooming of the ALD film. To transfer the pattern into the underlying layers, a plasma etch process may be used. For example, for a Sn-based CVD resist film, a H₂ or H₂/CH₄ plasma may be used to remove the unexposed resist material.

Embodiments of the present technology are further illustrated through the following non-limiting examples.

### Example 1

An EUV-patternable film is deposited on three silicon wafer substrates using a CVD process, using t-butyl tris(dimethylamino) tin as an organometallic precursor and water vapor as counter-reactant. The substrate and the deposition chamber walls are maintained at a temperature of about 70° C. The process is conducted at a pressure of about 2 Torr.

The organometallic precursor is introduced to the deposition chamber via a bubbler using Argon carrier gas at a flow rate of about 200 standard cubic centimeter per minute. The counter-reactant is water, delivered using a vaporizer at about 50 mg/minute. The precursors are introduced to the deposition chamber via two separate injection inlets and then mixed in the space above the substrate.

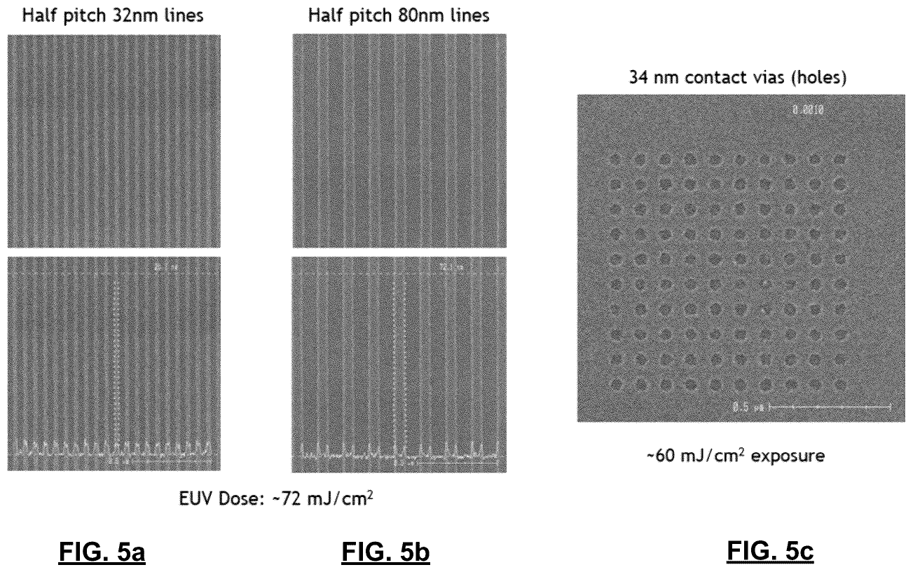

A polymeric organometallic film is deposited on the surface of the substrates, having a thickness of about 40 nm, as further described below. The substrates are then baked at 150° C. for 2 minutes and developed for about 15 seconds in 2-heptanone followed by a 15 second rinse using the same solvent. FIGS. 5a, 5b and 5c are scanning electron microscope images of the substrates after development.

In particular, two of the substrates are patterned using EUV in the Micro-field Exposure Tool 3 (MET3) at the Lawrence Berkeley National Laboratory (LBNL), at an exposure of about 72 mJ/cm², to define 1:1 line space features on the surface of the film at 32 nm and 80 nm half pitch, respectively. Images of the resulting substrates are shown in FIGS. 5a and 5b, respectively. The third substrate is patterned using EUV at an exposure of about 60 mJ/cm² to define 34 nm contact vias on the surface of the film. An image of the resulting substrate is shown in FIG. 5c.

### Example 2

An EUV-patternable film is deposited on two silicon wafer substrates using a CVD process, using iso-propyl tris(dimethylamino) tin as an organometallic precursor and water vapor as counter-reactant. The second silicon wafer has a 50 nm amorphous carbon underlayer. The substrate and the deposition chamber walls are maintained at a temperature of about 70° C. The process is conducted at a pressure of about 2 Torr.

The organometallic precursor is introduced to the deposition chamber via a bubbler using argon carrier gas at a flow rate of about 25 standard cubic centimeter per minute. The counter-reactant is delivered using a vaporizer at about 50 mg/minute. Both precursors are introduced to the deposition chamber via two sets of separate paths in a dual-plenum showerhead and then mixed in the space above the substrate. The temperature of the showerhead is set at 85° C.

A polymeric organometallic film is deposited on the surface of the substrate, having a thickness of about 20 nm on both wafers. The first wafer is patterned using EUV in the EUV interference Lithography (EUV-IL) tool at Paul Scherrer Institut (PSI), at an exposure of about 75-80 mJ/cm², to define 1:1 line/space features on the surface of the film at 26 and 24 nm pitch. The second wafer with amorphous carbon underlayer is then patterned using EUV in the Micro-field Exposure Tool 3 (MET3) at the Lawrence Berkeley National Laboratory (LBNL), at an exposure of about 64 mJ/cm², to define 1:1 line/space features on the surface of the film at 36 nm pitch. Both substrates are then baked at about 180° C. for about 2 minutes and developed for about 15 seconds in 2-heptanone followed by a 15 second rinse using the same solvent. The wet-developed pattern on the second silicon wafer is then transferred into the 50 nm carbon underlayer using a helium/oxygen plasma process.

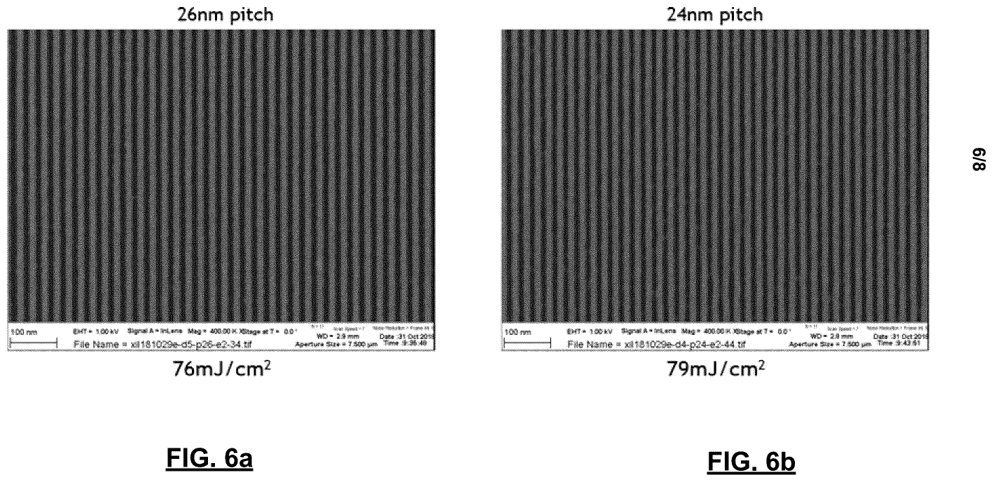

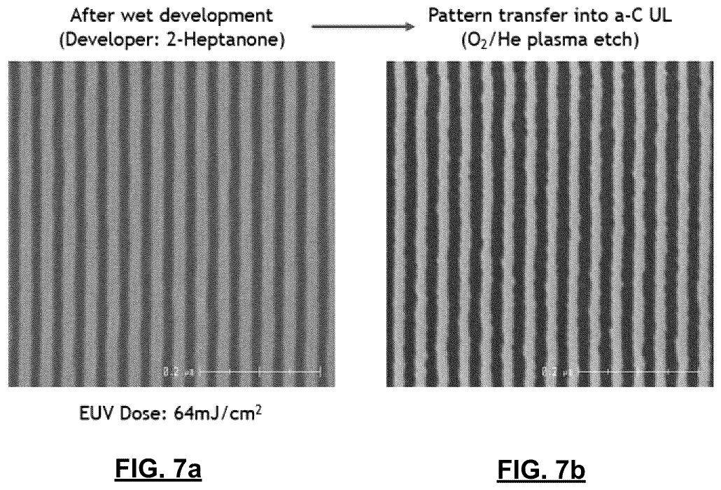

FIGS. 6a and 6b are scanning electron microscope images of the first substrate after development, wherein FIG. 6a shows the substrate having features at 26 nm pitch, exposed at 76 mJ/cm², and FIG. 6b shows the substrate having features at 24 nm pitch, exposed at 79 mJ/cm². FIGS. 7a and 7b are scanning electron microscope images of the second substrate after development (FIG. 7a) and after pattern transfer (FIG. 7b).

### Example 3

An EUV-patternable film is deposited on a silicon wafer substrate using a CVD process, using iso-propyl tris(dimethylamino) tin as an organometallic precursor and water vapor as counter-reactant. The silicon wafer has 50 nm deep line/space topography constructed prior to the deposition. The deposition conditions are identical to the process described in Example 2.

A polymeric organometallic film is deposited on the surface of the substrate, having a thickness of about 10 nm, covering the topography on the silicon wafer. The wafer with pre-existing topography is patterned using EUV in the EUV interference Lithography (EUV-IL) tool at Paul Scherrer Institut (PSI), at an exposure of about 70 mJ/cm² to define 1:1 line/space features at three different pitches, 32 nm, 28 nm, and 26 nm. The substrate is then baked at 190° C. for 2 minutes and developed for about 15 seconds in 2-heptanone followed by a 15 second rinse using the same solvent. FIGS. 8a, 8b and 8c are scanning electron microscope images of the resist line/space pattern printed over the silicon topography at pitches of 32 nm (FIG. 8a), 28 nm (FIGS. 8b), and 26 nm (FIG. 8c) after development.

### Non-limiting Discussion of Terminology

The foregoing description is merely illustrative in nature and is in no way intended to limit the technology, its application, or uses. The broad teachings of the technology can be implemented in a variety of forms. Therefore, while this technology includes particular examples, the true scope of the technology should not be so limited since other modifications will become apparent upon a study of the drawings, the specification, and the following claims.

The headings (such as “Background” and “Summary”) and sub-headings used herein are intended only for general organization of topics within the present technology, and are not intended to limit the scope of the technology or any aspect thereof. In particular, subject matter disclosed in the “Background” may include novel technology and may not constitute a recitation of prior art. Subject matter disclosed in the “Summary” is not an exhaustive or complete technology of the entire scope of the technology or any embodiments thereof. Classification or discussion of a material within a section of this specification as having a particular utility is made for convenience, and no inference should be drawn that the material must necessarily or solely function in accordance with its classification herein when it is used in any given composition.

It should be understood that one or more steps within a method may be executed in different order (or concurrently) without altering the principles of the present technology. Further, although each of the embodiments is described above as having certain features, any one or more of those features described with respect to any embodiment of the technology can be implemented in and/or combined with features of any of the other embodiments, even if that combination is not explicitly described. In other words, the described embodiments are not mutually exclusive, and permutations of one or more embodiments with one another remain within the scope of this technology. For example, a component which may be A, B, C, D or E, or combinations thereof, may also be defined, in some embodiments, to be A, B, C, or combinations thereof.

As used herein, the phrase at least one of A, B, and C should be construed to mean a logical (A OR B OR C), using a non-exclusive logical OR, and should not be construed to mean “at least one of A, at least one of B, and at least one of C.”

As used herein, the words “prefer” or “preferable” refer to embodiments of the technology that afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the technology.

As used herein, the word “include,” and its variants, is intended to be non-limiting, such that recitation of items in a list is not to the exclusion of other like items that may also be useful in the materials, compositions, devices, and methods of this technology. Similarly, the terms “can” and “may” and their variants are intended to be non-limiting, such that recitation that an embodiment can or may comprise certain elements or features does not exclude other embodiments of the present technology that do not contain those elements or features.

Although the open-ended term “comprising,” as a synonym of non-restrictive terms such as including, containing, or having, is used herein to describe and claim embodiments of the present technology, embodiments may alternatively be described using more limiting terms such as “consisting of” or “consisting essentially of.” Thus, for any given embodiment reciting materials, components or process steps, the present technology also specifically includes embodiments consisting of, or consisting essentially of, such materials, components or processes excluding additional materials, components or processes (for consisting of) and excluding additional materials, components or processes affecting the significant properties of the embodiment (for consisting essentially of), even though such additional materials, components or processes are not explicitly recited in this application. For example, recitation of a composition or process reciting elements A, B and C specifically envisions embodiments consisting of, and consisting essentially of, A, B and C, excluding an element D that may be recited in the art, even though element D is not explicitly described as being excluded herein. Further, as used herein the term “consisting essentially of” recited materials or components envisions embodiments “consisting of” the recited materials or components.

“A” and “an” as used herein indicate “at least one” of the item is present; a plurality of such items may be present, when possible.

Numeric values stated herein should be understood to be approximate, and interpreted to be about the stated value, whether or not the value is modified using the word “about.” Thus, for example, a statement that a parameter may have value “of X” should be interpreted to mean that the parameter may have a value of “about X.” “About” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates variations that may arise from ordinary methods of manufacturing, measuring or using the material, device or other object to which the calculation or measurement applies.

As referred to herein, ranges are, unless specified otherwise, inclusive of endpoints and include technology of all distinct values and further divided ranges within the entire range. Thus, for example, a range of “from A to B” or “from about A to about B” is inclusive of A and of B. Further, the phrase “from about A to about B” includes variations in the values of A and B, which may be slightly less than A and slightly greater than B; the phrase may be read be “about A, from A to B, and about B.” Technology of values and ranges of values for specific parameters (such as temperatures, molecular weights, weight percentages, etc.) are not exclusive of other values and ranges of values useful herein.

It is also envisioned that two or more specific exemplified values for a given parameter may define endpoints for a range of values that may be claimed for the parameter. For example, if Parameter X is exemplified herein to have value A and also exemplified to have value Z, it is envisioned that Parameter X may have a range of values from about A to about Z. Similarly, it is envisioned that technology of two or more ranges of values for a parameter (whether such ranges are nested, overlapping or distinct) subsume all possible combination of ranges for the value that might be claimed using endpoints of the disclosed ranges. For example, if Parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

What is claimed is:

1. A method for making an EUV-patternable film on a surface of a substrate, comprising:
providing the substrate to a heated pedestal set at a surface temperature;
mixing a vapor stream of an organometallic precursor with a vapor stream of a counter-reactant capable of creating oxygen and/or sulfur bridges between metal atoms so as to form a polymerized organometallic material; and
depositing the polymerized organometallic material at a deposition rate onto the surface of the substrate to form the EUV-patternable film, wherein the deposition rate is inversely proportional to the surface temperature.

2. The method of claim 1, wherein the temperature of the substrate is at or below the temperature of the vapor stream of the organometallic precursor and the temperature of the vapor stream of the counter-reactant.

3. The method of claim 1, wherein the organometallic precursor has the formula MₐR_{b}L_{c},
wherein: M is a metal with an atomic absorption cross section of 1×10⁷ cm²/mol or higher; R is alkyl, such as CₙH₂ₙ₊₁, wherein n>3; L is a ligand, ion or other moiety which is reactive with the counter reactant; a≥1; b≥1; and c≥1.

4. The method of claim 3, wherein M is selected from the group consisting of tin, bismuth, antimony, and combinations thereof; R is selected from the group consisting i-propyl, n-propyl, t-butyl, i-butyl, n-butyl, sec-butyl, i-pentyl, n-pentyl, t-pentyl, sec-pentyl and mixtures thereof; and L is selected from the group consisting of amines, alkoxy, carboxylates, halogens, and mixtures thereof.

5. The method of claim 1, wherein the organometallic precursor is t-butyl tris(dimethylamino) tin, i-butyl tris(dimethylamino) tin, n-butyl (tris)dimethylamino tin, sec-butyl tris(dimethylamino) tin, i-propyl(tris)dimethylamino tin, n-propyl (tris)dimethylamino tin, and analogous alkyl(tris)(t-butoxy) tin compounds.

6. The method of claim 1, wherein the organometallic precursor is partially fluorinated.

7. The method of claim 1, wherein the counter-reactant is selected from the group consisting of water, hydrogen peroxide, di- or polyhydroxy alcohols, hydrogen sulfide, hydrogen disulfide, trifluoroacetaldehyde monohydrate, fluorinated di-or polyhydroxy alcohols, and fluorinated glycols.

8. The method of claim 1, wherein the mixing and depositing are performed in a continuous chemical vapor deposition process.

9. A method for making an EUV-patternable film on a surface of a substrate, comprising:
providing, in a process chamber, the substrate to a heated pedestal set at a surface temperature;
flowing a vapor stream of an organometallic precursor via a first plenum of a dual-plenum showerhead to the process chamber;
flowing a vapor stream of a counter-reactant capable of creating oxygen and/or sulfur bridges between metal atoms to form a mixture used to form a polymerized organometallic material via a second plenum of the showerhead; and
depositing the polymerized organometallic material at a deposition rate onto the surface of the substrate to form the EUV-patternable film, wherein the deposition rate is inversely proportional to the surface temperature.

10. The method of claim 9, wherein the temperature of the substrate is at or below the temperature of the vapor stream of the organometallic precursor and the temperature of the vapor stream of the counter-reactant.

11. The method of claim 9, wherein the organometallic precursor has the formula MₐR_{b}L_{c},
wherein: M is a metal with an atomic absorption cross section of 1×10⁷ cm²/mol or higher; R is alkyl, such as CₙH₂ₙ₊₁, wherein n≥3; L is a ligand, ion or other moiety which is reactive with the counter reactant; a≥1; b≥1; and c≥1.

12. The method of claim 11, wherein M is selected from the group consisting of tin, bismuth, antimony, and combinations thereof; R is selected from the group consisting i-propyl, n-propyl, t-butyl, i-butyl, n-butyl, sec-butyl, i-pentyl, n-pentyl, t-pentyl, sec-pentyl and mixtures thereof; and L is selected from the group consisting of amines, alkoxy, carboxylates, halogens, and mixtures thereof.

13. The method of claim 9, wherein the organometallic precursor is t-butyl tris(dimethylamino) tin, i-butyl tris(dimethylamino) tin, n-butyl(tris)dimethylamino tin, sec-butyl tris(dimethylamino) tin, i-propyl(tris)dimethylamino tin, n-propyl(tris)dimethylamino tin, and analogous alkyl(tris)(t-butoxy) tin compounds.

14. The method of claim 9, wherein the organometallic precursor is partially fluorinated.

15. The method of claim 9, wherein the counter-reactant is selected from the group consisting of water, hydrogen peroxide, di- or polyhydroxy alcohols, hydrogen sulfide, hydrogen disulfide, trifluoroacetaldehyde monohydrate, fluorinated di- or polyhydroxy alcohols, and fluorinated glycols.

16. The method of claim 9, wherein the mixing and depositing are performed in a continuous chemical vapor deposition process.

17. The method of claim 9, further comprising:
exposing a region of the EUV-patternable film to EUV light to form an exposed film region, such that the EUV-patternable film also comprises an unexposed film region that is not exposed to the EUV light.

18. The method of claim 17, wherein the exposed film region of the mask precursor is insoluble and the unexposed film region of the mask precursor is soluble in a selected solvent.

19. A method for forming a lithographic mask precursor on a surface of a semiconductor substrate, comprising:
providing the semiconductor substrate to a heated pedestal set at a surface temperature;
mixing a vapor stream of an organometallic precursor with a vapor stream of a counter-reactant so as to form a polymerized organometallic material, wherein the organometallic precursor has the formula MₐR_{b}L_{c}, wherein: M is a metal with an atomic absorption cross section of 1×107 cm²/mol or higher; R is alkyl, such as CnH2n+1, wherein n≥3; L is a ligand or ion which is reactive with the counter reactant; a≥1; b≥1; and c≥1, and wherein the counter-reactant is selected from the group consisting of water, peroxides, di- or polyhydroxy alcohols, fluorinated di- or polyhydroxy alcohols, fluorinated glycols, and mixtures thereof; and
depositing the polymerized organometallic material at a deposition rate onto the surface of the semiconductor substrate to form an EUV-patternable film, wherein the deposition rate is inversely proportional to the surface temperature.

20. The method of claim 19, wherein the temperature of the semiconductor substrate is at or below the temperature of the vapor stream of the organometallic precursor and the temperature of the vapor stream of the counter-reactant.
